(19) United States
(12) Patent Application Publication
(10) Pub. No.: US 2024/0377434 A1
(43) Pub. Date: Nov. 14, 2024

(54) MEMS PROBE MODULE STRUCTURE

(71) Applicant: TAIWAN MASK CORPORATION, Hsinchu (TW)

(72) Inventors: SHANG-KUANG WU, HSINCHU (TW); YU-TSUNG FU, HSINCHU (TW); MING-WEI HUANG, HSINCHU (TW)

(21) Appl. No.: 18/196,665

(22) Filed: May 12, 2023

(51) Int. Cl. G01R 1/073; B81B 1/00; G01R 1/067

(52) U.S. Cl. CPC G01R 1/07307; B81B 1/008; G01R 1/06755; B81B 2201/12; B81B 2203/0118; B81B 2207/07

(57) ABSTRACT

A micro-electromechanical system (MEMS) probe module structure is provided, including: a ceramic carrier and a plurality of probes fixed on the ceramic carrier; the ceramic carrier has a top surface, a side surface, and a bottom surface, and a window in the center; the ceramic carrier is provided with a plurality of lead wires, each lead wires are distributed on the top surface, the side surface and the bottom surface and connected together; the bottom surface is provided with a plurality of bonding areas, and each lead wire is connected to a corresponding bonding area; each of the probes includes a needle tip and the needle arm, the needle tup is arranged at one end of the needle arm, and the needle arm is welded to the bonding area, so that the needle arm extends below the window like a cantilever and the needle tip faces downward.

### BACKGROUND OF THE INVENTION

### 1. Field of the Invention

The present invention relates generally to a microelectromechanical system (MEMS) probe, and more particularly, to a MEMS probe module structure to facilitate precise assembly.

### 2. The Prior Arts

Micro-electromechanical system (MEMS) is a semiconductor process technology that can form tiny mechanical components, usually at the micron to millimeter level, into chips using integrated circuits. MEMS probes are tiny-size probes made of the MEMS technology. A micro-electromechanical probe module is a structure that integrates a substrate with a circuit and a plurality of probes. With such a structure, it is easy to assemble with a lens set and a circuit board into a probe for chip testing in the subsequent process.

FIG. 6 shows a schematic cross-sectional view of a conventional probe module, the probe module includes a ceramic substrate 51, a circuit layer 52, and a probe 53, the probe 53 is a micro-electromechanical probe, including a needle tip 531, a needle arm 532 and a base 533. The circuit layer 52 is a multi-layer circuit board, which uses a multi-layer metal lead wire structure to form 3D circuits inside. The ceramic substrate 51 is electrically connected to the base 533 of the probe 53 via the circuit layer 52, and the ceramic substrate 51 has a groove 511 in the middle. However, this structure has the following disadvantages:
1. In order to make the probe 53 have the cushioning characteristics of the cantilever probe, the probe 53 must have a base 533, and there is a small distance from the groove 511; however, adding a layer of pedestal 533 must add at least one process for the type of probe 53 manufactured by MEMS technology, which will complicate the structure and the manufacturing process is more time-consuming. In addition, it is necessary to etch a through hole in the base 533 and fill the base 533 with metal for electrical contact to facilitate the subsequent alignment and bonding with the circuit layer 52 on the ceramic substrate 51, making assembly more difficult and cumbersome.
2. The circuit layer 52 is a multi-layer 3D circuit formed inside. The circuits must be interlaced and avoid contact, which makes the distance between the circuits too short, and the signal is likely to interfere during the test, which affects the test.
3. Although the circuit layer 52 can be directly made of semiconductors on the ceramic substrate 51, the formation of a multi-layer 3D circuit structure is relatively complicated in the manufacturing process.

### SUMMARY OF THE INVENTION

In order to solve the aforementioned problems, the primary objective of the present invention is to provide a MEMS probe module structure, to simplify the structure of the MEMS probe; that is, the present invention eliminates the base structure in the conventional micro-electromechanical probe, and the probes facilitate faster and more precise mounting on ceramic substrates.

In order to achieve the above objective, the present invention provides a MEMS probe module structure, comprising: a ceramic carrier and a plurality of probes fixed on the ceramic carrier; the ceramic carrier having a top surface, a side surface, and a bottom surface, with a viewing window disposed in the center, and the ceramic carrier being disposed with a plurality of lead wires distributed on the top surface, the side surface, and the bottom surface and connected together; the bottom surface being disposed with a plurality of bonding areas, and each lead wire being connected to a corresponding bonding area; each probe comprising a needle tip and a needle arm, the needle tip being disposed at one end of the needle arm, and the needle arm being welded to the corresponding bonding area from the end far away from the needle tip, so that the needle arm extending below the viewing window with the needle tip facing downward as a cantilever.

In a preferred embodiment of the present invention, the bottom surface is also provided with at least one groove, the groove communicates with the viewing window, a plurality of the bonding areas are adjacent to the groove, and the depth of the groove is greater than a distance that the needle arm can offset from the position of the needle tip.

In a preferred embodiment of the present invention, the needle tip is made of nickel-cobalt-phosphorus alloy.

In a preferred embodiment of the present invention, the needle arm is made of nickel-cobalt alloy.

In a preferred embodiment of the present invention, the needle tip also comprises a tip of a smaller size, and the tip is made of nickel-cobalt-phosphorus alloy.

The advantage of the MEMS probe module structure of the present invention is that because the structure of the probe is simplified, it is easier to manufacture with MEMS technology at a reduced cost, and the plurality of probes can be aligned and bonded to the ceramic carrier faster and more accurate. Moreover, a plurality of lead wires are exposed to form a 3D circuit on the ceramic carrier, which is relatively easy to manufacture, and can avoid information interference due to the increased spacing between adjacent lead wires during testing, which produces excellent results and maintains good test quality.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a perspective bottom view of a MEMS probe module structure of the present invention;

FIG. 2 is a partial enlarged view in FIG. 1

FIG. 3 is an enlarged view of the section AA of FIG. 1;

FIG. 4 is a perspective top view of a MEMS probe module structure of the present invention;

FIG. 5 is a bottom view of the MEMS probe module structure of the present invention;

FIG. 6 is a schematic cross-sectional view of a conventional probe module.

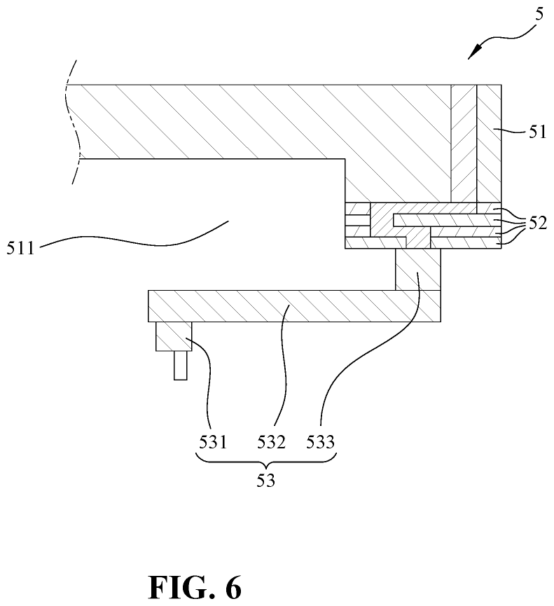

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention. It should be noted that when an element is said to be “fixed” or “mounted” to another element, it means that it may be directly on another element or there may be an intervening element. When an element is said to be “connected” to another element, it means that it may be directly connected to the other element or intervening elements may also be present. In the illustrated embodiment, the directions meaning up, down, left, right, front and rear, etc. are relative to explain that the structure and movement of the different components are relative in this case. These representations are pertinent when the components are in the positions shown in the figures. However, if the description of the location of elements changes, these representations are considered to change accordingly.

Unless otherwise defined, all technical and scientific terms used herein have the same meaning as commonly understood by those skilled in the technical field of the present invention. The terminology used herein is for the purpose of describing particular embodiments only and is not intended to be limiting of the invention. As used herein, the term “and/or” includes any and all combinations of one or more of the associated listed items.

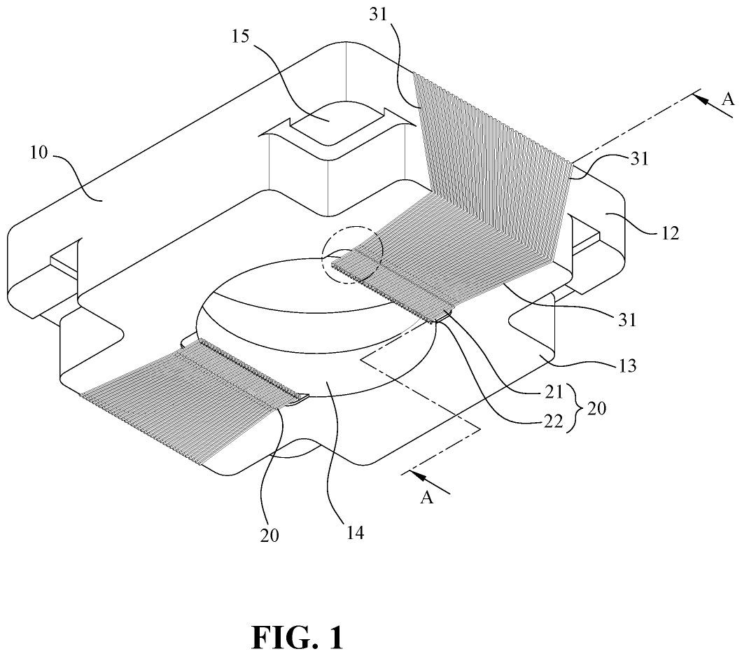

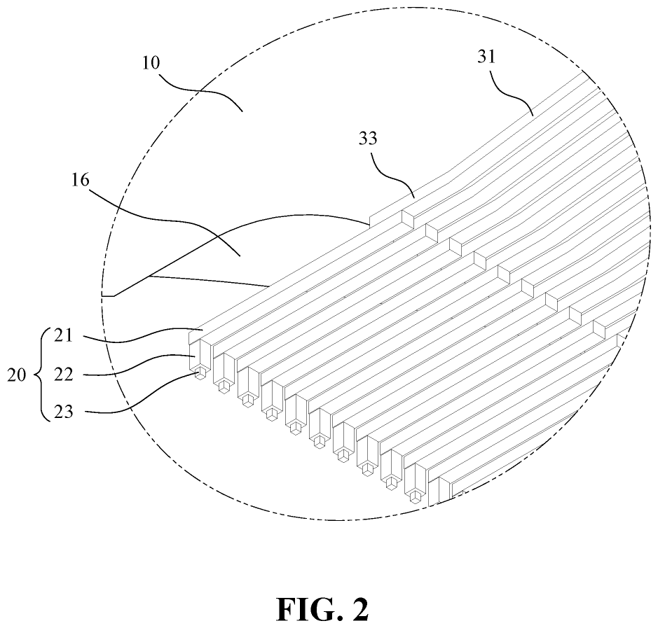

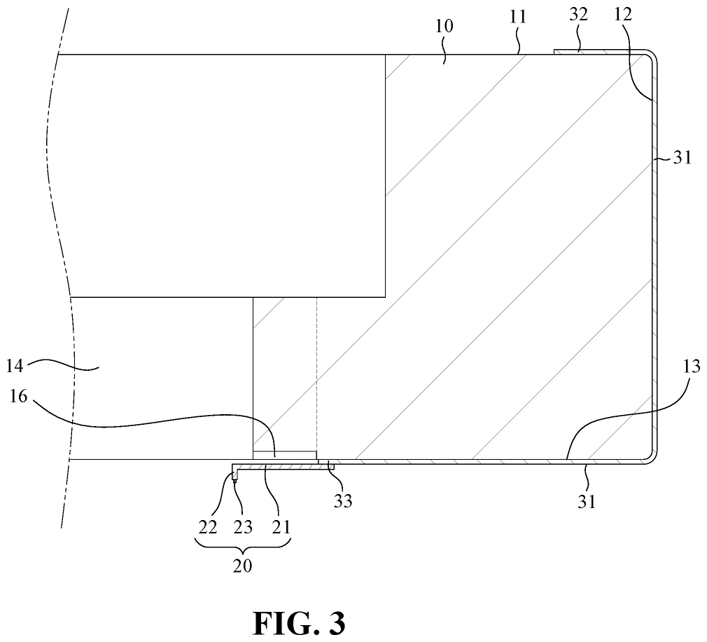

FIG. 1 is a perspective bottom view of a MEMS probe module structure of the present invention; FIG. 2 is a partial enlarged view in FIG. 1 FIG. 3 is an enlarged view of the section AA of FIG. 1. The MEMS probe module structure of the present invention includes: a ceramic carrier 10 and a plurality of probes 20 fixed on the bottom surface of the ceramic carrier 10.

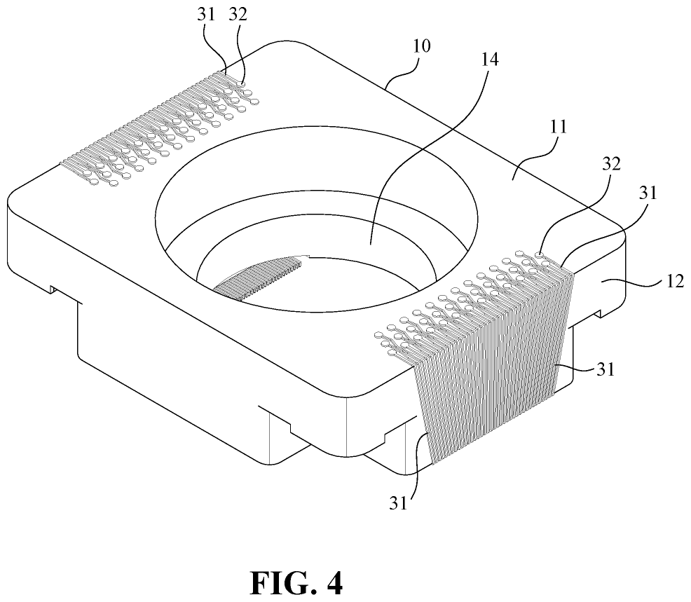

The ceramic carrier 10 is made of ceramic insulating material, has high strength and small thermal expansion coefficient, and can avoid deformation caused by high temperature during the testing process, to prevent changes in the correct positions of the probes 20. The ceramic carrier 10 is provided with an exposed 3D circuit formed by a plurality of lead wires 31, and the lead wires 31 are used for electrical signal transmission with the corresponding probe 20. In the present embodiment, the ceramic carrier 10 is a rectangular shape, as shown in FIG. 4 FIG. The ceramic carrier 10 has a top surface 11, a side surface 112, and a bottom surface 13, and is disposed with a through viewing window at the center. The four corners of the ceramic carrier 10 have internally recessed positioning portions 15. The bottom surface 13 also forms at least one groove 16, and the groove 16 communicates with the viewing window 14. The viewing window 14 is used for installing a lens assembly.

A plurality of lead wires 31 are distributed on the top surface 11, the side surface 12, and the bottom surface 13 and are connected to each other to form an exposed three-dimensional circuit. As such, the distance between the lead wires 31 increases. For example, the distance between the adjacent lead wires 31 located on the bottom surface 13 closest to the viewing window 14 is the smallest, and then the distance between the adjacent leads 31 near the side surface 12 also increases. The distance between adjacent lead wires 31 gradually increases from bottom to top. The advantage of increasing the distance between lead wires 31 is that signal interference is less likely to occur during testing. In addition, in the present embodiment, the top surface 11 is also provided with a plurality of copper pads 32, and the bottom surface 13 is provided with a plurality of bonding areas 33, and each lead wire 31 is connected to the copper pad 32 and the bonding area 33 at the corresponding position. The adjacent lead wires 31 are not in contact with each other. The lead wire 31 protrudes from the top surface 11, the side surface 12, and the bottom surface 13. In addition, because the present invention can increase the distance between the two adjacent leads 31, it also helps to increase the distance and size between the copper pads 32, which facilitates subsequent electrical alignment and bonding with the circuit board.

The ceramic carrier 10 is fixed with a plurality of probes 20, and each probe 20 includes a needle arm 21 and a needle tip 22. The needle arm 21 is welded to the corresponding bonding area 33 from an end away from the needle tip 22, so that the needle arm 21 extends below the viewing window 14 like a cantilever and the needle tip 22 faces downward. The present invention simplifies the probe 20 into an L-shaped body formed by the needle arm 21 and the needle tip 22, which simplifies the shape of the needle arm 21 and facilitates the alignment between one end of the needle arm 21 and the bonding area 33 and welding directly. This method can reduce the manufacturing difficulty and cost of the probe 20. In addition, in the present embodiment, the needle tip 22 has a two-stage needle body, which further includes a smaller tip 23. Furthermore, the probe 20 is made of nickel-cobalt-phosphorus alloy in order to increase hardness to improve wear resistance and prolong service life. In the present embodiment, the needle tip 22 and tip 23 are made of nickel-cobalt-phosphorus alloy, and the needle arm 21 is made of nickel-cobalt alloy.

Next, an explanation will be made on the welding operation between the probe 20 and the ceramic carrier 10 of the present invention, which is also different from the conventional method. The plurality of probes 20 is processed into a probe chip by MEMS semiconductor process, and the probe chip includes a plurality of probes 20 and insulating silicon material between adjacent probes. Before bonding, the surface of the bonding area 33 is plated with silver or tin, and moreover, the probe chip is tin-plated at the position to be welded; that is, one end of the needle arm 21, and then the probe chip is bonded to the bonding area 33 in an environment of 250° C. The bonding time is about 8 minutes from heating up to cooling down. After that, the probe chip bonded to the ceramic carrier 10 is etched with potassium hydroxide (KOH) to remove the silicon material between the adjacent probes 20, and the probes 20 are peeled off from the probe chip. At this point, the bonding operation between the ceramic carrier 10 and the probes 20 is completed. This method can quickly and accurately complete the bonding operation between the probes 20 and the ceramic carrier 10.

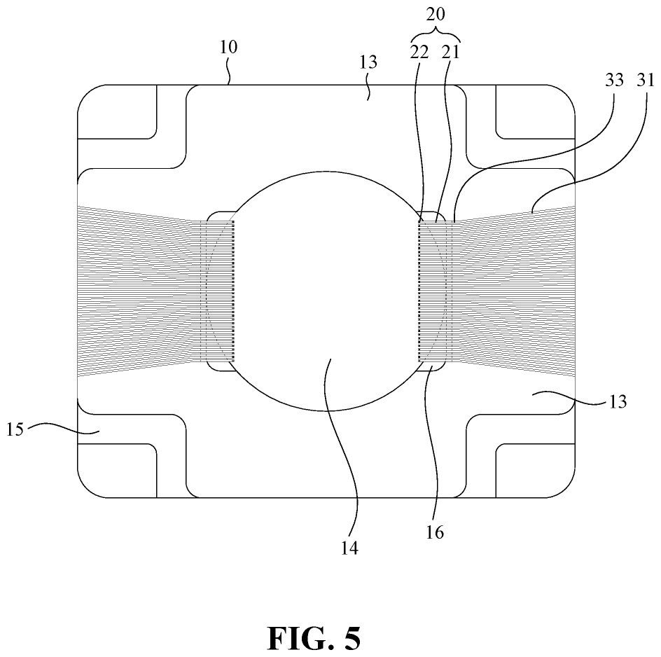

As shown in FIG. 3 and FIG. 5, in the present embodiment, the viewing window 14 is a circular through hole. The probes 20 are generally arranged in a square array. In order not to hinder the cantilever effect of the probes 20, at least one groove 16 is formed on the bottom surface 13 of the present invention. The groove 16 communicates with the viewing window 14, and the depth of the groove 16 is greater than the distance that the needle arm 21 can offset at the position of the needle tip 22. The bonding area 33 is located adjacent to the edge of the groove 16, that is, the vertical wall of the groove 16 is parallel to a plurality of the bonding areas 33, so that when one end of the needle arm 21 is welded to the bonding area 33, the needle arm 21 of the probes 20 located at the two sides (upper and lower positions in FIG. 4) still has the effect of buffering and offsetting the cantilever.

In summary, the MEMS probe module structure of the present invention is to directly fix the plurality of probes 20 on the bottom surface of the ceramic carrier 10. Without the base structure of conventional probes, the complexity and the cost manufacturing process are greatly reduced. The 3D circuit formed by the lead wires 31 exposed on the ceramic carrier 10 not only has a relatively simple processing method, but also can reduce signal interference problems during testing, which is beneficial for testing. The practical and progressive MEMS probe module structure of the present invention meets the needs of current semiconductor industry.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A micro-electromechanical system (MEMS) probe module structure, comprising:
a ceramic carrier, having a top surface, a side surface, and a bottom surface, with a viewing window disposed in the center, and the ceramic carrier being disposed with a plurality of lead wires distributed on the top surface, the side surface, and the bottom surface and connected together; the bottom surface being disposed with a plurality of bonding areas, and each lead wire being connected to a corresponding bonding area; and
a plurality of probes fixed on the ceramic carrier, each probe comprising a needle tip and a needle arm, the needle tip being disposed at one end of the needle arm, and the needle arm being welded to the corresponding bonding area from the end far away from the needle tip, so that the needle arm extending below the viewing window with the needle tip facing downward as a cantilever.

2. The MEMS probe module structure according to claim 1, wherein the bottom surface is also provided with at least one groove, the groove communicates with the viewing window, a plurality of the bonding areas are adjacent to the groove, and the depth of the groove is greater than a distance that the needle arm can offset from the position of the needle tip.

3. The MEMS probe module structure according to claim 1, wherein the needle tip is made of nickel-cobalt-phosphorus alloy.

4. The MEMS probe module structure according to claim 1, wherein the needle arm is made of nickel-cobalt alloy.

5. The MEMS probe module structure according to claim 1, wherein the needle tip further comprises a tip of a smaller size, and the tip is made of nickel-cobalt-phosphorus alloy.
